(19) United States
(12) Patent Application Publication
(10) Pub. No.: US 2007/0211777 A1
(43) Pub. Date: Sep. 13, 2007

(54) Laser diode array beam translator

(76) Inventor: Sergey Simavoryan, San Diego, CA (US)

Correspondence Address: COOLEY GODWARD KRONISH LLP;ATTN: Patent Group, Suite 500, 1200 - 19th Street, NW, Washington, DC, 20036-2402, US

(21) Appl. No.: 11/638,325

(22) Filed: Dec. 12, 2006

Related U.S. Application Data
(60) Provisional application No. 60/750,084, filed on Dec. 12, 2005.

(51) Int. Cl. H01S 3/30; H01S 5/00

(52) U.S. Cl. 372/50.12; 372/6

(57) ABSTRACT

A laser diode array beam translator includes a laser diode array having a number of spaced-apart laser elements, or diodes, each emitting laser radiation. The typical laser diode array laser elements are rectangular in shape, and linearly spaced apart along an axis with the long dimensions of the element along the axis. A number of optical fibers, or waveguides, having rectangular cross-sections are placed adjacent each laser element and sized horizontally and vertically to approximate the rectangular dimensions of the laser element. The optical fibers rotate ninety degrees (90°) from a horizontal configuration to a vertical configuration. Once the fibers are in the vertical configuration, due to the flexible nature of the rectangular fibers in their short-dimension direction, the optical fibers translate horizontally so that the output ends of the rectangular fibers are parallel and adjacent to a receiving end of an optical fiber. The proximity and similar sizing of the receiving end of the optical fiber to the combined size of the rectangular optical fibers provides for the near total reception of the optical energy from the rectangular fibers to the optical fiber.

### RELATED APPLICATIONS

This application claims the benefit of priority to U.S. Provisional Patent Application Ser. No. 60/750,084 entitled “Laser Bar Beam Delivery Adapter” filed Dec. 12, 2005, and currently co-pending.

### FIELD OF THE INVENTION

The present invention pertains generally to optical devices. The present invention is more particularly, though not exclusively, useful for combining the optical outputs of multiple elements in a laser diode array into a single optical fiber.

### BACKGROUND OF THE INVENTION

Laser arrays, in particular laser diode arrays (LDA), have long been known to provide a cost effective way of building a distributed source for high power laser applications. While somewhat cost effective, it is often very difficult to effectively transform the lateral laser array into a single optical output, such as a single optical fiber.

Over the years, a number of approaches have been developed to direct and combine the outputs of multiple LDAs to a single optical output. However, these solutions are often very complex and far too difficult to reliably create. Due to the very small tolerances and detailed manufacturing techniques, these devices are often prohibitively expensive to manufacture.

One device developed to combine multiple laser outputs to a single optical fiber is disclosed in U.S. Pat. No. 5,185,758 entitled “Multiple Laser-Pump Optical System” which issued to T. Fan, et al. in 1993. The Fan device includes a lens array carefully positioned in front of the laser elements to collimate the diverging light from the element. The light is then focused to a region, or spot, of high optical power to pump that region with the laser light from multiple laser elements.

Another device developed to combine multiple LDA outputs to a single fiber is shown and described in U.S. Pat. No. 5,594,752 entitled “Diode Laser Source With Concurrently Driven Light Emitting Segments” which issued to J. Endriz in 1997. Like the Fan device, the Endriz apparatus includes an array of laser segments which each emit laser light which passes through a collimating lens assembly (lenslets) to form a plurality of collimated beams. These collimated beams pass through a common convergent lens array to focus upon a single point, such as the core of an optical fiber.

While the devices disclosed by Fan and Endiz may indeed serve the purpose of increasing the laser light intensity at the point of focus, it is very difficult to manufacture these devices due to the need for very precise positioning in the placement of the laser elements, lenslets, convergent lens and optical fiber. As a result of this high-precision manufacturing, these devices are very expensive to manufacture, and prone to failure due to vibration and impact.

In light of the above, it would be advantageous to provide a device capable of receiving laser light from an LDA and effectively and reliably directing the laser light to a common optical output, such as an optical fiber.

### SUMMARY OF THE INVENTION

The Laser Diode Array Beam Translator of the present invention includes a laser diode array having a number of spaced-apart laser elements, or diodes, each emitting laser radiation. The typical laser diode array laser elements are rectangular in shape, and linearly spaced apart along an axis with the long dimensions of the element along the axis.

A number of optical fibers, or waveguides, having rectangular cross-sections are placed adjacent each laser element and sized horizontally and vertically to approximate the rectangular dimensions of the laser element. The proximity and similar sizing of the input end of the rectangular optical fiber to the laser element provides for the near total reception of the optical energy from the laser element into the fiber.

As the rectangular fibers extend away from the laser diode array, the optical fibers are rotated ninety degrees (90°) from a horizontal configuration to a vertical configuration. Once the fibers are in the vertical configuration, due to the flexible nature of the rectangular fibers in their short-dimension direction, the optical fibers translate horizontally so that the output ends of the rectangular fibers are parallel and adjacent.

The output ends of the rectangular fibers are adjacent to a receiving end of an optical fiber. The proximity and similar sizing of the receiving end of the optical fiber to the combined size of the rectangular optical fibers provides for the near total reception of the optical energy from the rectangular fibers to the optical fiber.

### BRIEF DESCRIPTION OF THE DRAWINGS

The nature, objects, and advantages of the present invention will become more apparent to those skilled in the art after considering the following detailed description in connection with the accompanying drawings, in which like reference numerals designate like parts throughout, and wherein:

FIG. 1 is a perspective view of the Laser Diode Array Beam Translator of the present invention showing a laser diode array coupled to an optical fiber having a rectangular cross-section and rotating from a horizontal orientation to a vertical orientation for translation in a horizontal axis;

FIG. 2 is a side view of the Laser Diode Array Beam Translator of the present invention showing the placement of the laser diode array emitter with the input end of an optical fiber adjacent a laser diode and the fiber passing through a ninety-degree rotation from a horizontal configuration to a vertical configuration for placement adjacent an output fiber; and

FIG. 3 is a top plan view of the Laser Diode Array Beam Translator of the present invention showing the placement of the laser diode array, rectangular optical fiber and the output fiber, and details the rotation and routing of the rectangular optical fiber as it passes between the array and the output.

### DETAILED DESCRIPTION OF A PREFERRED EMBODIMENT

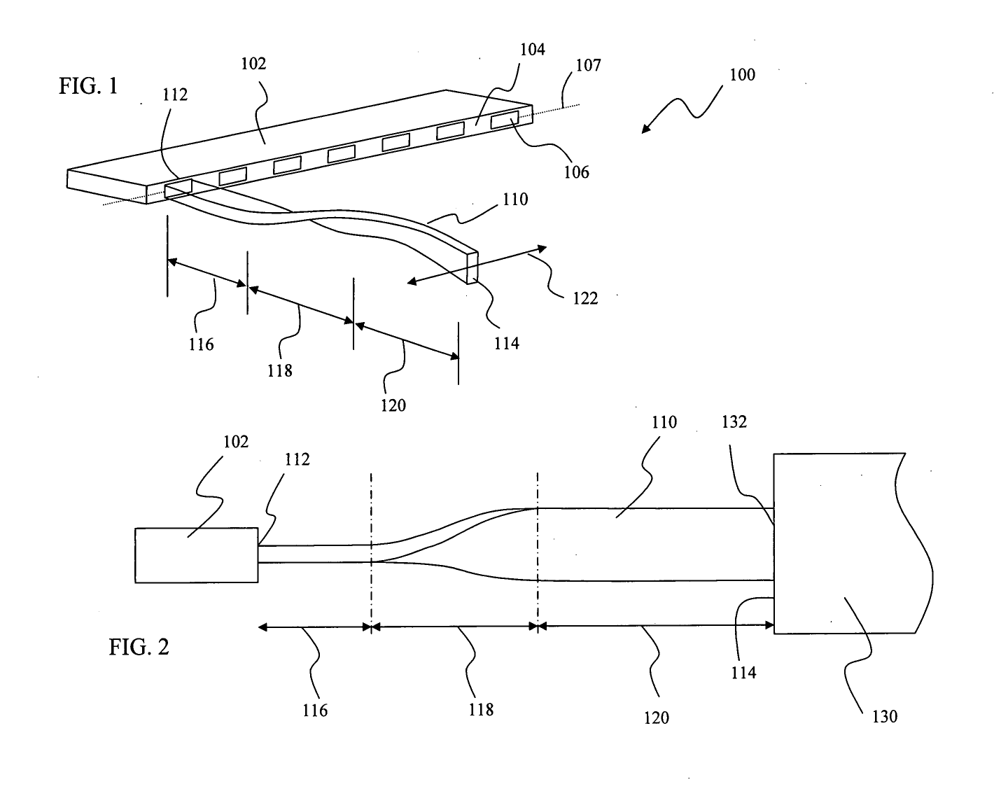

Referring initially to FIG. 1, a perspective view of the Laser Diode Array Beam Translator 100 of the present invention showing a laser diode array 102 having a face 104 equipped with a number of spaced-apart laser elements 106, or diodes, each emitting laser radiation. The typical laser diode array laser elements 106 are rectangular in shape, and linearly spaced apart along an axis 107 with the long dimensions of the element 106 along the axis.

An optical fiber 110 having a rectangular cross-section is adjacent each laser element 106. More specifically, the input end 112 of optical fiber 110 is in close proximity to laser element 106. Because the optical fibers are adjacent each laser element, and have rectangular cross-sections sized horizontally and vertically to approximate the rectangular dimensions of the laser element, nearly all laser light emitted from the laser element 106 is received within fiber 110. This is particularly advantageous as this method of optical coupling eliminates the need for complicated and precise lens structures such as were required with prior devices. This simplifies the manufacturing process, and greatly increases the reliability of the present invention.

In a preferred embodiment, optical fiber 110 may have rectangular cross-sectional dimensions of 160 microns×4 microns, but other dimensions are fully contemplated herein. For instance, in embodiments where the laser emitter has a different dimension, it may be advantageous to utilize fibers 110 having similar dimensions.

From FIG. 1, three (3) distinct sections are identified along the length of fiber 110 from the input end 112 to the output end 114. The fiber 110 is in a horizontal configuration, where the longer dimension of the rectangular fiber is horizontal and parallel to axis 107. This configuration is maintained in horizontal configuration section 116 as the fiber extends away from laser diode array 102. In rotational section 118, the rectangular fiber 110 rotates ninety degrees (90°) so that the longer dimension of the rectangular fiber 110 is in the vertical direction as the fiber 110 passes into the vertical section 120. In the vertical section 120, the fiber can be translated horizontally in direction 122 to position the fibers 110.

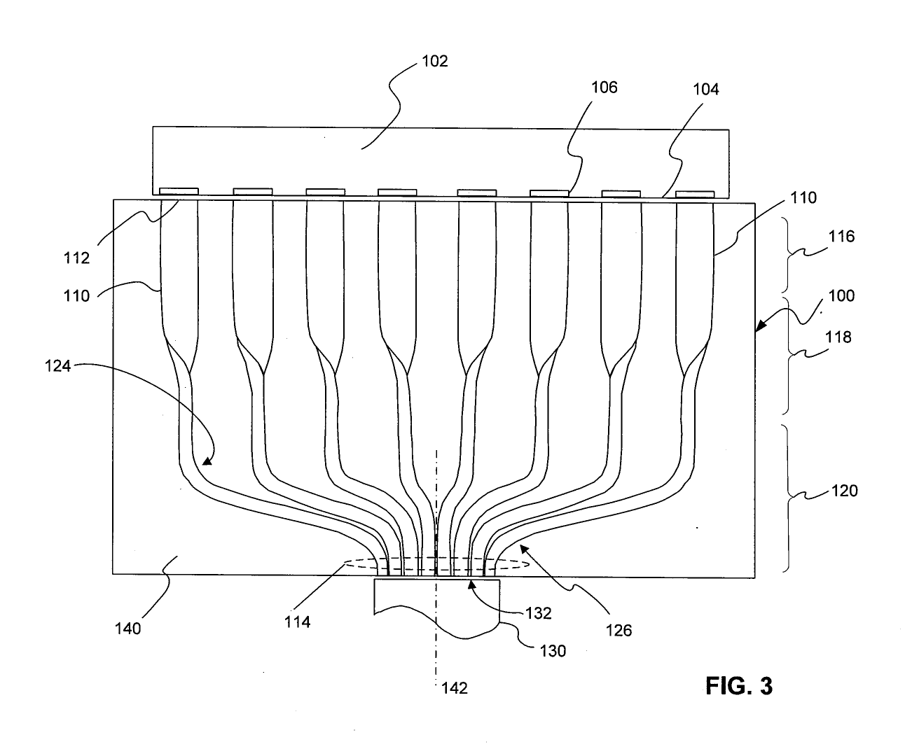

Referring now to FIG. 2, a side view of the Laser Diode Array Beam Translator of the present invention is shown and details the placement of the laser diode array 102 with the input end 112 of an optical fiber 110 adjacent a laser diode (not shown this Figure). The fiber 110 is shown having three sections, namely the horizontal configuration section 116, the rotational section 118 in which the fiber 110 passes through a ninety-degree rotation from a horizontal configuration to a vertical configuration, and the vertical section 120 for placement adjacent the input 132 of an output fiber 130.

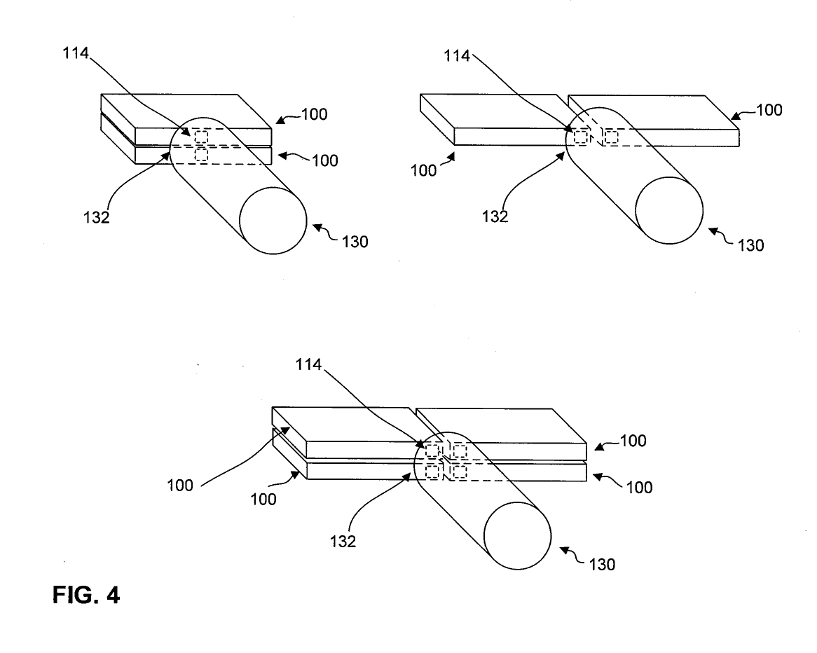

A top plan view of the Laser Diode Array Beam Translator 100 of the present invention is shown in FIG. 3. For alignment and mounting purposes, a substrate 140 may be used to anchor and attach the components discussed in translator 100 using techniques known in the art. The laser diode array 102 is securely attached to substrate 140 and the input ends 112 of rectangular optical fibers 110 are securely positioned adjacent to laser elements 106 on face 104 of array 102. Fibers 110 may be secured in place using optical grade epoxy or other fastening techniques known in the art.

The fibers 110 extend away from laser array 102 through horizontal configuration section 116. Following section 116, the fibers 110 pass into rotational configuration section 118 in which the optical fibers are rotated ninety degrees (90°) from the horizontal configuration in section 116 to a vertical configuration in section 120.

Once the fibers 110 are in the vertical configuration, due to the flexible nature of the rectangular fibers in their short-dimension direction, the optical fibers 110 can translate horizontally in direction 122 (shown in FIG. 1) so that the output ends 114 of the rectangular fibers 110 are parallel and adjacent. The output ends 114 of the rectangular fibers 110 are positioned adjacent to a receiving end 132 of an optical fiber 130. The proximity of the output ends 114 of fibers 110 to receiving end 132 of fiber 130, and the similar sizing of the receiving end 132 of the optical fiber 130 to the combined size of the rectangular optical fibers 110 provides for the near total reception of the optical energy from the rectangular fibers 110 to the optical fiber 130. The output end of fibers 110 positionally correspond to the input of an output fiber, such as a round 120 micron diameter optical fiber, such that the output ends 114, when adjacent, are within the outer dimensions of the output fiber 130.

The length of fiber within each section 116, 118 and 120 may vary depending on the manufacturer's specifications for each fiber. In some cases, the optical fiber 110 may be very flexible providing for a shortened rotational section 118 and a shortened vertical orientation section 120. It is important to the reliability and durability of the present invention that no stress cracks are formed on the outside of bends, and compression fractures are formed on the fibers 110 as they are positioned. Specifically, each fiber 110 has a minimum bend radius, such as radii 124 and 126 which must not be exceeded. These specifications may vary depending on the particular materials and dimensions of fibers 110.

While the embodiment of the present invention 100 shown in FIG. 3 is symmetrical about the axis 142, it is to be appreciated that such symmetry is not required to stay within the scope of the present invention. Further, while the optical fibers 110 are shown to pass continuously through sections 116, 118 and 120 as a single length of fiber, it is to be appreciated that the various sections could be built separately or integrated into a unified structure from fiber segments.

From FIG. 3, it may be appreciated that the laser diode array 102 may have more or fewer laser elements 106. In some common embodiments, laser diode arrays contain 19 laser elements 106. The embodiments shown in conjunction with the present description are merely exemplary of a preferred embodiment, and variations are fully contemplated herein.

The present invention may also include multiple assemblies 100. For instance, in order to achieve additional laser energy at the input 132 of output fiber 130, multiple assemblies 100 may be stacked together and positioned adjacent each other so that substrates 140 are parallel to provide a larger size and higher energy output.

While other advantages of the Laser Diode Array Beam Translator 100 of the present invention will become apparent to those skilled in the art, the present invention provides several advantages over prior devices, including the near lossless design for signal propagation and the ability to combine a large number of laser emitters into a single output using a relatively small sized device.

The present invention also does not require collimation of the laser emitters and thus there are no critical alignment issues with lenslets which in turn minimizes vibration concerns and simplifies the manufacturing and minimizes the costs of the device.

Due to the flexible nature of the assembly using fibers 110, there are no limitations on density of distribution of laser emitters, and allows for the maximum optical power density and application using any wavelength from laser and LED sources.

While there have been shown what are presently considered to be preferred embodiments of the present invention, it will be apparent to those skilled in the art that various changes and modifications can be made herein without departing from the scope and spirit of the invention

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A laser array translator, comprising:
a plurality of waveguides, each of said plurality of waveguides including:
an input having a first orientation;
an output having a second orientation;
a body extending along a longitudinal axis between said input and said output, said body being of a substantially rectangular cross-section having a longer dimension and a shorter dimension;
wherein said second orientation of said output of at least a first of said plurality of waveguides is rotated with respect to said first orientation of said input of said first waveguide about said longitudinal axis of said first of said plurality of waveguides.

13. The laser diode translator of claim 12, wherein said inputs of said plurality of waveguides are disposed to accept electromagnetic output from a plurality of laser diodes positioned on a common substrate.

14. The laser array translator of claim 12, wherein said inputs of said plurality of waveguides are disposed to accept electromagnetic output from a plurality of laser diodes mounted in a co-linear array.

15. The laser array translator of claim 12, wherein ones of said inputs of said plurality of waveguides are disposed to align with corresponding ones of a plurality of laser sources such that substantially all output energy provided by said plurality of laser sources is coupled to said waveguides.

16. The laser array translator of claim 15 wherein a surface of a first of said inputs of said plurality of waveguides is positionally aligned in contact or in near contact with a first of a surface of said plurality of laser sources such that the surface area of said inputs overlaps the surface area of said laser sources.

17. The laser array translator of claim 12, wherein each of said outputs of said plurality of waveguides are disposed to align with an optical fiber such that substantially all output energy of said plurality of waveguides is coupled to said optical fiber.

18. The laser array translator of claim 17, wherein said optical fiber is of a round cross-sectional dimension.

19. The laser array translator of claim 17, wherein said optical fiber is of a rectangular cross-sectional dimension.

20. The laser array translator of claim 17 wherein a surface of each of said outputs of said plurality of waveguides is positionally aligned in contact or in near contact with a surface of said optical fiber such that the surface area of said optical fiber overlaps the surface area of said outputs.

21. The laser array translator of claim 12 wherein said rotation of said second orientation of said output about said longitudinal axis of said waveguide comprises a substantially 90 degree rotation with respect to said first orientation of said input.

22. The laser array translator of claim 12 wherein each said waveguide comprises a substantially horizontal section, a substantially vertical section, and a rotational section.

23. The laser array translator of claim 22 wherein two or more of said substantially horizontal section, said substantially vertical section, and said rotational section comprise separate elements affixed to form each of said waveguides.

24. The laser array translator of claim 12 wherein at least one said waveguide of said plurality of waveguides comprises a first bend and a second bend, said first and second bends translating said output of said waveguide with respect to an axis normal to said input of said waveguide.

25. A laser array translator, comprising:
a plurality of waveguide arrays, each of said plurality of waveguide arrays including a plurality of waveguides wherein each of said plurality of waveguides includes:
an input having a first orientation;
an output having a second orientation;
a body extending along a longitudinal axis between said input and said output, said body being of a substantially rectangular cross-section having a longer dimension and a shorter dimension;
wherein said second orientation of said output of at least a first of said plurality of waveguides is rotated with respect to said first orientation of said input of said first of said waveguides about said longitudinal axes of said first of said plurality of waveguides; and
said outputs of said plurality of said waveguides are positioned substantially adjacent to comprise an output port.

26. The laser array translator of claim 25 wherein said output port is disposed to couple to an output fiber.

27. The laser array translator of claim 26 wherein said output fiber is a round optical fiber.

28. The laser array translator of claim 26 wherein said output fiber is a rectangular optical fiber.

29. The laser array translator of claim 25 wherein at least one said waveguide of said plurality of waveguides comprises a first bend and a second bend, said first and said second bends disposed to translate said output of said waveguide with respect to an axis normal to said input of said waveguide.

30. An optical coupling system comprising:
a laser electromagnetic radiation source;
an output optical fiber; and
a laser array combiner, said laser array combiner including:
a plurality of waveguides, each said waveguide comprising:
an input having a first orientation;
an output having a second orientation;
a body extending along a longitudinal axis between said input and said output, said body being of a substantially rectangular cross-section having a longer dimension and a shorter dimension;
wherein said second orientation of said output of at least a first of said plurality of waveguides is rotated with respect to said first orientation of said input of said first of said plurality of waveguides about said longitudinal axes of said first of said plurality of waveguides.

31. The optical coupling system of claim 30 wherein said laser electromagnetic radiation source comprises a laser diode array.

32. The optical coupling system of claim 30 wherein said rotation of said second orientation of said output about said longitudinal axis of said waveguide comprises a substantially 90 degree rotation with respect to said first orientation of said input.

33. The optical coupling system of claim 30 wherein at least one said waveguide of said plurality of waveguides comprises a first bend and a second bend, said first and said second bends disposed to translate said output of said waveguide with respect to an axis normal to said input of said waveguide.
